(19) United States
(12) Patent Application Publication
(10) Pub. No.: US 2026/0082695 A1
(43) Pub. Date: Mar. 19, 2026

(54) SEMICONDUCTOR STACK

(71) Applicant: SUMITOMO ELECTRIC INDUSTRIES, LTD., Osaka (JP)

(72) Inventors: Takuma FUYUKI, Osaka (JP); Susumu YOSHIMOTO, Osaka (JP); Shunsuke FUJII, Osaka (JP); Takeshi AOKI, Osaka (JP); Kenshi TAKADA, Osaka (JP); Suguru ARIKATA, Osaka (JP); Takahiro YASUNAMI, Osaka (JP)

(73) Assignee: SUMITOMO ELECTRIC INDUSTRIES, LTD., Osaka (JP)

(21) Appl. No.: 19/329,637

(22) Filed: Sep. 16, 2025

(30) Foreign Application Priority Data
Sep. 18, 2024 (JP) 2024-161308

(51) Int. Cl. H10D 86/00

(52) U.S. Cl. CPC H10D 86/201

(57) ABSTRACT

A semiconductor stack includes a substrate formed of silicon, an oxide buffer layer formed of any one of zirconia, hafnia, and composite oxides of zirconia and hafnia, an alignment layer formed of gallium arsenide, and a compound semiconductor layer formed of a III-V compound semiconductor. The substrate, the oxide buffer layer, the alignment layer, and the compound semiconductor layer are stacked in this order.

### CROSS REFERENCE TO RELATED APPLICATIONS

This application claims priority based on Japanese Patent Application No. 2024-161308 filed on Sep. 18, 2024, and the entire contents of the Japanese patent application are incorporated herein by reference.

### TECHNICAL FIELD

The present disclosure relates to a semiconductor stack.

### BACKGROUND

A semiconductor stack in which a compound semiconductor layer formed of a III-V compound semiconductor is stacked on a substrate formed of silicon is known. By using a substrate formed of silicon, the cost of the material can be reduced.

However, in the case of using a substrate formed of silicon, when a compound semiconductor layer is directly grown on the substrate, a large number of crystal defects may occur in the compound semiconductor layer due to the influence of the difference in lattice constant between silicon and the III-V compound semiconductor.

From such a viewpoint, a substrate formed of silicon is made into an off-angle substrate (for example, see Patent Literature: Japanese Unexamined Patent Application Publication No. 2012-9777). In the off-angle substrate, the main surface of the substrate is formed to have an off-angle of about several degrees with respect to the (100) plane, for example, depending on the required performance and conditions of the device.

By adopting the off-angle substrate, a buffer layer can be formed, by the off-angle substrate, between the substrate formed of silicon and the compound semiconductor layer formed of the III-V compound semiconductor. As a result, the crystallinity of the compound semiconductor layer formed of the III-V compound semiconductor can be improved while using the substrate formed of silicon.

### SUMMARY

A semiconductor stack according to the present disclosure includes a substrate formed of silicon, an oxide buffer layer formed of any of zirconia, hafnia, and a composite oxide of zirconia and hafnia, an alignment layer formed of gallium arsenide, and a compound semiconductor layer formed of a III-V compound semiconductor. The substrate, the oxide buffer layer, the alignment layer, and the compound semiconductor layer are stacked in this order.

### BRIEF DESCRIPTION OF THE DRAWINGS

FIG. 1 is a schematic cross-sectional view illustrating a structure of a semiconductor stack according to an embodiment.

FIG. 2 is a flow chart outlining a method of manufacturing the semiconductor stack according to the embodiment.

FIG. 3 is a schematic cross-sectional view for explaining an oxide buffer layer forming step in the method of manufacturing the semiconductor stack according to the embodiment.

FIG. 4 is a schematic cross-sectional view for explaining an alignment layer forming step in the method of manufacturing a semiconductor stack according to the embodiment.

FIG. 5 is a schematic cross-sectional view for explaining a surface flatness enhancement layer forming step in the method of manufacturing a semiconductor stack according to the embodiment.

### DETAILED DESCRIPTION

The cost of manufacturing a substrate including a surface with an off-angle is higher compared to the cost of manufacturing a substrate without an off-angle. Thus, the semiconductor stack adopting the off-angle substrate has a problem that the manufacturing cost is high even when the substrate formed of silicon is used. Thus, the object of the present disclosure is to provide a semiconductor stack having a reduced number of crystal defects while reducing costs in the semiconductor stack in which a compound semiconductor layer formed of a III-V compound semiconductor is disposed on a substrate formed of silicon.

According to the present disclosure, the semiconductor stack having a reduced number of crystal defects while reducing costs in the semiconductor stack in which a compound semiconductor layer formed of a III-V compound semiconductor is disposed on a substrate formed of silicon can be provided.

First, embodiments of the present disclosure will be listed and described.

(1) A semiconductor stack according to the present disclosure includes a substrate formed of silicon, an oxide buffer layer formed of any one of zirconia, hafnia, and composite oxides of zirconia and hafnia, an alignment layer formed of gallium arsenide, and a compound semiconductor layer formed of a III-V compound semiconductor. The substrate, the oxide buffer layer, the alignment layer, and the compound semiconductor layer are stacked in this order.

In the semiconductor stack of the present disclosure, the oxide buffer layer and the alignment layer are disposed between the substrate and the compound semiconductor layer, and thus, even when there is a difference in lattice constant between the substrate and the compound semiconductor layer, the crystallinity of the compound semiconductor layer can be improved. Thus, it is not necessary to use the off-angle substrate. As a result, in a semiconductor stack in which a compound semiconductor layer formed of a III-V compound semiconductor is disposed on a substrate formed of silicon, the number of crystal defects can be reduced while reducing the cost.

(2) In the above (1), the semiconductor stack may further include a surface flatness enhancement layer disposed between the alignment layer and the compound semiconductor layer. A roughness of a main surface of the surface flatness enhancement layer facing the compound semiconductor layer may be smaller than a roughness of a main surface of the alignment layer facing the surface flatness enhancement layer. By adopting such a configuration, the crystallinity of the compound semiconductor layer can be further improved.

(3) In the above (1) or (2), a thickness of the alignment layer may be smaller than a thickness of the oxide buffer layer. By adopting such a configuration, the overall thickness of the semiconductor stack can be reduced.

(4) In the above (2), the surface flatness enhancement layer may be formed of gallium phosphide or gallium antimonide. By adopting such a configuration, the crystallinity of the compound semiconductor layer can be easily improved.

Next, embodiments of a semiconductor stack according to the present disclosure will be described below with the reference to the drawings. It is noted that, in the drawings, the same or corresponding components are denoted by the same reference numerals, and description thereof will not be repeated.

### (Overview of Structure of Semiconductor Stack 1)

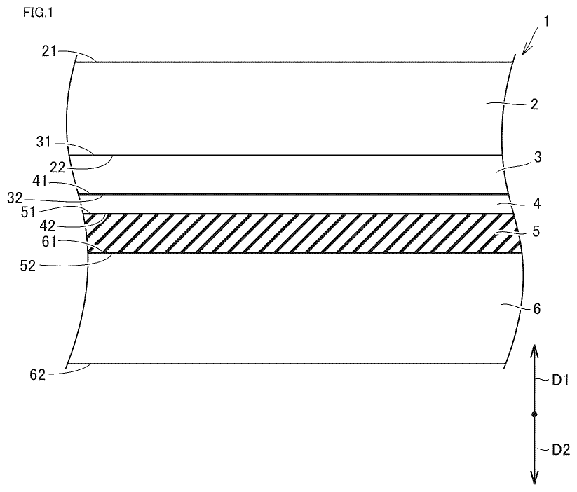

FIG. 1 is a schematic cross-sectional view showing the structure of a semiconductor stack 1. Referring to FIG. 1, the semiconductor stack 1 according to the present embodiment includes a substrate 6, an oxide buffer layer 5, an alignment layer 4, a surface flatness enhancement layer 3, and a compound semiconductor layer 2. The substrate 6, the oxide buffer layer 5, the alignment layer 4, the surface flatness enhancement layer 3, and the compound semiconductor layer 2 are stacked in this order. Hereinafter, in the stacking direction, a direction from the substrate 6 toward the compound semiconductor layer 2 is defined as a “first direction D1”, and the opposite direction is defined as a “second direction D2”.

The substrate 6 is formed of silicon (Si). The compound semiconductor layer 2 is formed of a III-V compound semiconductor. Although there is a difference in lattice constant between the substrate 6 and the compound semiconductor layer 2, the compound semiconductor layer 2 is less likely to be affected by the difference in lattice constant because the oxide buffer layer 5 and the alignment layer 4 are disposed between the substrate 6 and the compound semiconductor layer 2 in the semiconductor stack 1 according to the present embodiment. Although there is a difference in thermal expansion coefficient between the substrate 6 and the compound semiconductor layer 2, the compound semiconductor layer 2 is less likely to be affected by the difference in thermal expansion coefficient because the oxide buffer layer 5 is disposed between the substrate 6 and the compound semiconductor layer 2 in the semiconductor stack 1. As a result, in the semiconductor stack 1 according to the present embodiment, the crystallinity of the compound semiconductor layer 2 is improved. The substrate 6 may be a substrate without an off-angle, in order to reduce costs.

In the present disclosure, the expression “formed of (a certain element)” means that the element is formed using the certain element, and may include an element other than the certain element. The expression “consist of (a certain element)” means that the composition does not contain any element other than the certain element. However, the phrase “consist of (a certain element)” may include impurities. Examples of the impurity include a dopant for the purpose of adjusting an appropriate conductivity type (for example, P-type or N-type).

### (Substrate 6)

The substrate 6 is a semiconductor substrate formed of silicon. The substrate 6 according to the present embodiment consists of a single crystal of silicon. Referring to FIG. 1, the substrate 6 has a first main surface 61 and a second main surface 62. The first main surface 61 is a surface of the substrate 6 facing the first direction D1. The first main surface 61 according to the present embodiment is a plane orthogonal to the first direction D1. The second main surface 62 is a surface of the substrate 6 facing the second direction D2. The second main surface 62 according to the present embodiment is a plane orthogonal to the second direction D2. The first main surface 61 and the second main surface 62 are parallel to each other. The thickness of the substrate 6 is not particularly limited, but is, for example, 50 μm to 5 mm.

In the present embodiment, the first main surface 61 of the substrate 6 is formed of a (100) plane. The Miller index of the first main surface 61 in the substrate 6 is not particularly limited, and may be, for example, a (111) plane or a (101) plane. The Miller index of the second main surface 62 in the substrate 6 is not particularly limited. The second main surface 62 of the substrate 6 is formed of, for example, a (100) plane.

### (Oxide Buffer Layer 5)

The oxide buffer layer 5 is stacked on the first main surface 61 of the substrate 6. The oxide buffer layer 5 according to the present embodiment is formed of epitaxially grown zirconia (ZrO₂) on the first main surface 61 of the substrate 6. In addition, the oxide buffer layer 5 may be formed of hafnia (HfO₂) or a composite oxide of zirconia and hafnia.

The oxide buffer layer 5 has a first main surface 51 and a second main surface 52. The first main surface 51 is a surface of the oxide buffer layer 5 facing the first direction D1. The first main surface 51 according to the present embodiment is a plane orthogonal to the first direction D1. The first main surface 51 of the oxide buffer layer 5 faces the alignment layer 4. The second main surface 52 is a surface of the oxide buffer layer 5 facing the second direction D2. The second main surface 52 according to the present embodiment is a plane orthogonal to the second direction D2. The second main surface 52 faces the first main surface 61 of the substrate 6 and is in contact with each other. In the oxide buffer layer 5, the first main surface 51 and the second main surface 52 are parallel to each other. The thickness of the oxide buffer layer 5 is, for example, 10 nm to 30 nm, and more specifically, 15 nm to 25 nm. The thickness of the oxide buffer layer 5 can be, for example, 25 nm.

When the alignment layer 4 is stacked on the oxide buffer layer 5, the alignment layer 4 is epitaxially grown in a state where the substrate 6 is heated to a predetermined temperature or higher, so that the crystal structure of the oxide buffer layer 5 is changed in accordance with the crystal structure of the alignment layer 4. The predetermined temperature is 600° C. or higher, and may be 650° C. or higher, or 700° C. or higher. The crystallinity of the compound semiconductor layer 2 is improved by disposing the oxide buffer layer 5 between the substrate 6 and the compound semiconductor layer 2.

The oxide buffer layer 5 is formed of any of zirconia, hafnia, or a composite oxide of zirconia and hafnia, and thus is dissolved by hydrofluoric acid. Hydrofluoric acid hardly affects the compound semiconductor layer 2. Thus, for example, by dissolving the oxide buffer layer 5 using hydrofluoric acid at the time of use, the substrate 6 can be removed from the compound semiconductor layer 2 while reducing the influence on the compound semiconductor layer 2.

### (Alignment Layer 4)

The alignment layer 4 is stacked on the first main surface 51 of the oxide buffer layer 5. The alignment layer 4 according to the present embodiment is formed of epitaxially grown gallium arsenide (GaAs) on the first main surface 51 of the oxide buffer layer 5. The alignment layer 4 may be a single crystal. The alignment layer 4 may be formed as a single crystal in the first direction D1 from the oxide buffer layer 5 and as a polycrystal formed of a plurality of crystals along the main surface. By disposing the alignment layer 4 between the oxide buffer layer 5 and the compound semiconductor layer 2, the compound semiconductor layer 2 is easily grown in a state of being aligned in a certain direction. As a result, the crystal plane of the compound semiconductor layer 2 can be the same as the crystal plane of the first main surface 61 of the substrate 6.

The alignment layer 4 has a first main surface 41 and a second main surface 42. The first main surface 41 is a surface of the alignment layer 4 facing the first direction D1. The first main surface 41 of the alignment layer 4 faces the surface flatness enhancement layer 3. The second main surface 42 is a surface of the alignment layer 4 facing the second direction D2. The second main surface 42 faces the first main surface 51 of the oxide buffer layer 5 and is in contact with each other.

In the alignment layer 4, the first main surface 41 and the second main surface 42 are parallel to each other. The alignment layer 4 according to the present embodiment has a thickness smaller than a thickness of the oxide buffer layer 5. This makes it possible to make the thickness of the semiconductor stack 1 relatively small. However, the thickness of the alignment layer 4 may be equivalent to the thickness of the oxide buffer layer 5. The thickness of the alignment layer 4 is, for example, 10 nm to 30 nm, and more specifically, 15 nm to 25 nm. The thickness of the alignment layer 4 can be, for example, 20 nm. As used in the present disclosure, “equivalent” includes the extent to which the compared objects are substantially the same. For example, when the difference between the thickness of the alignment layer 4 and the thickness of the oxide buffer layer 5 is less than 1 nm, the difference is included in “equivalent”. In the present disclosure, “thickness” means the minimum value of thickness unless otherwise specified.

The second main surface 42 in the alignment layer 4 has the same Miller index as the first main surface 61 in the substrate 6. In the alignment layer 4 according to the present embodiment, the second main surface 42 is formed of a (100) plane. The second main surface 42 in the alignment layer 4 has the same Miller index as the first main surface 41, and is specifically formed of a (100) plane.

### (Surface Flatness Enhancement Layer 3)

The surface flatness enhancement layer 3 is stacked on the first main surface 41 of the alignment layer 4. The surface flatness enhancement layer 3 according to the present embodiment is formed of epitaxially grown gallium phosphide (GaP) on the first main surface 41 of the alignment layer 4. The surface flatness enhancement layer 3 is not limited to gallium phosphide. For example, it may also be formed of gallium antimonide (GaSb). The surface flatness enhancement layer 3 is disposed between the alignment layer 4 and the compound semiconductor layer 2, and thus the crystallinity of the compound semiconductor layer 2 can be improved.

The surface flatness enhancement layer 3 includes a first main surface 31 and a second main surface 32. The first main surface 31 is a surface of the surface flatness enhancement layer 3 facing the first direction D1. The first main surface 31 according to the present embodiment is a plane orthogonal to the first direction D1. The first main surface 31 of the surface flatness enhancement layer 3 faces the compound semiconductor layer 2. The second main surface 32 is a surface of the surface flatness enhancement layer 3 facing the second direction D2. The second main surface 32 according to the present embodiment is a plane orthogonal to the second direction D2. The second main surface 32 faces the first main surface 41 of the alignment layer 4 and is in contact with each other.

The first main surface 31 and the second main surface 32 of the surface flatness enhancement layer 3 have fine irregularities. The roughness of the first main surface 31 is smaller than the roughness of the second main surface 32. That is, in the semiconductor stack 1, the roughness of the first main surface 31 of the surface flatness enhancement layer 3 facing the compound semiconductor layer 2 is smaller than the roughness of the first main surface 41 of the alignment layer 4 facing the surface flatness enhancement layer 3. The roughness in the present disclosure can be measured, for example, as follows. An arbitrary cross section is taken in the semiconductor stack 1, and a roughness curve along a boundary line with a surface in contact with each of the first main surface 31 and the second main surface 32 is extracted. The mean line is calculated from the roughness curve. A reference length is extracted from the roughness curve in a direction parallel to the average line, and in the extracted portion, a numerical value obtained by calculating the sum of the average value of the absolute values of the heights of the first to fifth peaks from the peak most protruding from the average line in the first direction D1 and the average value of the absolute values of the depths of the first to fifth valleys from the valley most depressed from the average line in the second direction D2 is used as an index. The larger the index is, the rougher the surface roughness can be evaluated. By comparing these indexes, the roughness of the first main surface 31 and the roughness of the second main surface 32 can be compared.

The thickness of the surface flatness enhancement layer 3 according to the present embodiment is, for example, 10 nm to 500 nm, and more specifically, can be 20 nm to 50 nm.

### (Compound Semiconductor Layer 2)

The compound semiconductor layer 2 is stacked on the first main surface 31 of the surface flatness enhancement layer 3. The compound semiconductor layer 2 according to the present embodiment is formed of an epitaxially grown III-V compound semiconductor on the first main surface 31 of the surface flatness enhancement layer 3. Examples of the III-V compound semiconductor include gallium arsenide (GaAs), indium phosphide (InP), and indium arsenide (InAs). The compound semiconductor layer 2 may be a single crystal. The compound semiconductor layer 2 may be formed in a large number of columnar crystal bodies extending from the surface flatness enhancement layer 3 in the first direction D1 and formed of a plurality of crystals along the main surface.

The compound semiconductor layer 2 has a first main surface 21 and a second main surface 22. The first main surface 21 is a surface of the compound semiconductor layer 2 facing the first direction D1. The first main surface 21 according to the present embodiment is a plane orthogonal to the first direction D1. The first main surface 21 of the compound semiconductor layer 2 is an end surface in the first direction D1 in the semiconductor stack 1 according to the present embodiment. The second main surface 22 is a surface of the compound semiconductor layer 2 facing the second direction D2. The second main surface 22 according to the present embodiment is a plane orthogonal to the second direction D2. The second main surface 22 faces the first main surface 31 of the surface flatness enhancement layer 3 and is in contact with each other.

In the compound semiconductor layer 2, the first main surface 21 and the second main surface 22 are parallel to each other. The thickness of the compound semiconductor layer 2 is larger than the total thickness of the oxide buffer layer 5 and the alignment layer 4. In the present embodiment, the thickness of the compound semiconductor layer 2 is larger than the total thickness of the oxide buffer layer 5, the alignment layer 4, and the surface flatness enhancement layer 3. Thus, the semiconductor stack 1 according to the present embodiment can reduce the overall thickness even when the oxide buffer layer 5 and the alignment layer 4 are disposed between the substrate 6 and the semiconductor stack 1. The thickness of the compound semiconductor layer 2 may be, for example, 1.5 μm or less. The thickness of the compound semiconductor layer 2 is, for example, 0.5 μm to 1.5 μm, and more specifically, 0.7 μm to 1.2 μm.

The crystal plane of the second main surface 22 in the compound semiconductor layer 2 has the same Miller index as the first main surface 31 in the surface flatness enhancement layer 3. The crystal plane of the second main surface 22 in the compound semiconductor layer 2 has the same Miller index as the first main surface 41 in the alignment layer 4. That is, the second main surface 22 in the compound semiconductor layer 2 has the same Miller index as the first main surface 61 in the substrate 6. The second main surface 22 in the compound semiconductor layer 2 according to the present embodiment is formed of the (100) plane. The crystal plane of the first main surface 21 in the compound semiconductor layer 2 has the same Miller index as the second main surface 22, and is formed of the (100) plane in the present embodiment.

### (Method of Manufacturing)

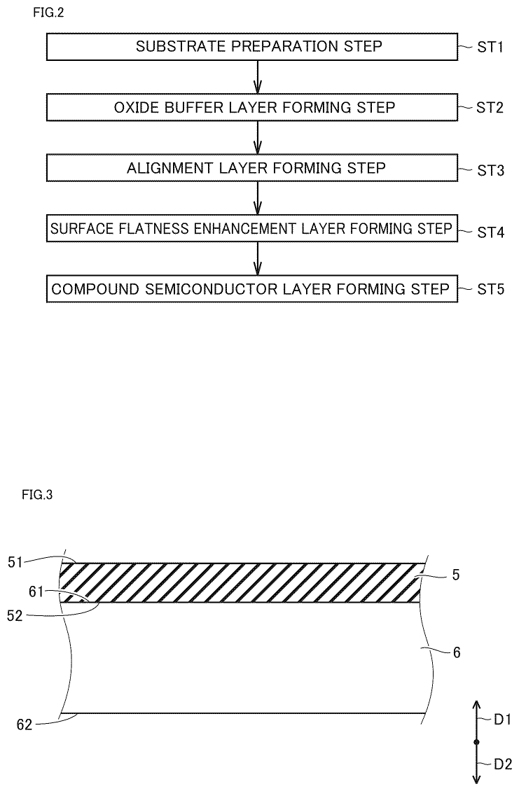

Next, an example of a method of manufacturing the semiconductor stack 1 according to the present embodiment will be described. FIG. 2 is a block diagram showing a procedure of a method of manufacturing the semiconductor stack 1 according to the present embodiment. Referring to FIG. 2, the method of manufacturing the semiconductor stack 1 according to the present embodiment includes a substrate preparation step, an oxide buffer layer forming step, an alignment layer forming step, a surface flatness enhancement layer forming step, and a compound semiconductor layer forming step. The substrate preparation step, the oxide buffer layer forming step, the alignment layer forming step, the surface flatness enhancement layer forming step, and the compound semiconductor layer forming step are performed in this order. When the semiconductor stack 1 without the surface flatness enhancement layer 3 is manufactured, the compound semiconductor layer forming step is performed without performing the surface flatness enhancement layer forming step after the alignment layer forming step is completed.

As a ST1 step, a substrate preparation step is performed. In the ST1 step, the substrate 6 formed of silicon is prepared. In the ST1 step, the substrate 6 having the first main surface 61 is prepared. Specifically, an ingot formed of silicon is sliced, and the substrate 6 is prepared through processes such as cleaning and drying.

Next, as a ST2 step, an oxide buffer layer forming step is performed. In the ST2 step, as shown in FIG. 3, the oxide buffer layer 5 is formed on the first main surface 61 of the substrate 6. Specifically, for example, the oxide buffer layer 5 including zirconia is stacked on the first main surface 61 of the substrate 6 by epitaxial growth.

The ST2 step is performed, for example, as follows. The substrate 6 is placed in a vacuum atmosphere and the substrate 6 is heated by a heater. The substrate 6 is heated to, for example, about 700° C. After the substrate 6 is heated, a high voltage is applied between the vapor deposition material and the substrate 6. The deposition material is zirconium (Zr) formed of a single crystal. In a state where a high voltage is applied between the vapor deposition material and the substrate 6, the vapor deposition material is irradiated with an electron beam from an electron gun. At this time, the evaporated zirconium reacts with oxygen on the substrate 6, and thus zirconia is formed on the first main surface 61 of the substrate 6. Thus, the oxide buffer layer 5 including zirconia may be formed on the first main surface 61 of the substrate 6 by epitaxial growth, and the oxide buffer layer forming step is completed.

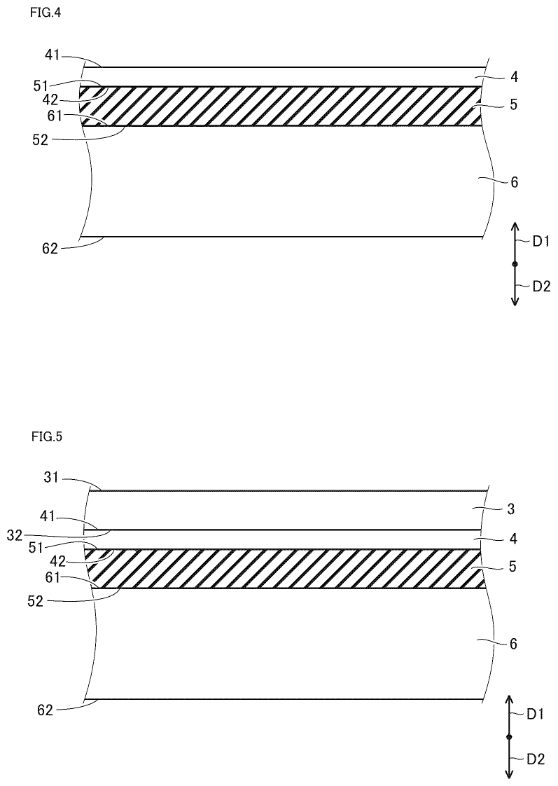

Next, as a ST3 step, an alignment layer forming step is performed. In the ST3 step, as shown in FIG. 4, the alignment layer 4 is formed on the first main surface 51 of the oxide buffer layer 5. Specifically, the alignment layer 4 formed of gallium arsenide is stacked on the first main surface 51 of the oxide buffer layer 5 by epitaxial growth.

The ST3 step is performed, for example, as follows. The substrate 6 on which the oxide buffer layer 5 is formed is placed in a growth furnace, and the substrate 6 is heated by a heater. The substrate 6 is heated to, for example, about 700° C. In this state, the alignment layer 4 is formed on the first main surface 51 of the oxide buffer layer 5 by vapor phase growth. Specifically, the alignment layer 4 can be formed by appropriately adjusting the pressure in the growth furnace while supplying the raw material gas so as to be in contact with the first main surface 51 of the oxide buffer layer 5. The alignment layer 4 is formed on the first main surface 51 of the oxide buffer layer 5, and thus the alignment layer forming step is completed.

Next, as a ST4 step, a surface flatness enhancement layer forming step is performed. In the ST4 step, as shown in FIG. 5, the surface flatness enhancement layer 3 is formed on the first main surface 41 of the alignment layer 4. Specifically, the surface flatness enhancement layer 3 formed of, for example, gallium phosphide is stacked on the first main surface 41 of the alignment layer 4 by epitaxial growth. In the ST4 step, the surface flatness enhancement layer 3 is formed on the first main surface 41 of the alignment layer 4 by, for example, vapor phase growth. The surface flatness enhancement layer 3 is formed on the first main surface 41 of the alignment layer 4, and thus the surface flatness enhancement layer forming step is completed.

Next, as a ST5 step, a compound semiconductor layer forming step is performed. Referring to FIG. 1, in the ST5 step, the compound semiconductor layer 2 is formed on the first main surface 31 of the surface flatness enhancement layer 3. Specifically, the compound semiconductor layer 2 formed of, for example, indium arsenide is stacked on the first main surface 31 of the surface flatness enhancement layer 3 by epitaxial growth. In the ST5 step, the compound semiconductor layer 2 is formed on the first main surface 31 of the surface flatness enhancement layer 3 by, for example, vapor phase growth. The compound semiconductor layer 2 is formed on the first main surface 31 of the surface flatness enhancement layer 3, and thus the compound semiconductor layer forming step is completed. Through the above steps, the fabrication of the semiconductor stack 1 according to the present embodiment is completed.

The material for forming the compound semiconductor layer 2 formed in the compound semiconductor layer forming step is not limited to indium arsenide as described above, and may be gallium arsenide (GaAs) or indium phosphide (InP), for example. Further, any compound semiconductor may be stacked on the compound semiconductor layer 2.

### (Modifications)

The oxide buffer layer 5 is formed of zirconia in the embodiment, but may be formed of hafnia (HfO₂). The oxide buffer layer 5 formed of hafnia is stacked on the first main surface 61 of the substrate 6 by epitaxial growth. In the oxide buffer layer forming step, the oxide buffer layer 5 formed of hafnia is formed by, for example, a pulsed laser deposition method. The oxide buffer layer 5 formed of hafnia is not limited to the pulse laser deposition method, and may be formed by another vapor deposition method (for example, a sputtering method). The oxide buffer layer 5 may be formed of a composite oxide of zirconia and hafnia.

In the embodiment, the surface flatness enhancement layer 3 is disposed between the alignment layer 4 and the compound semiconductor layer 2, but the surface flatness enhancement layer 3 may not be provided depending on, for example, the required crystallinity of the compound semiconductor layer 2. In this case, the first main surface 41 of the alignment layer 4 and the second main surface 22 of the compound semiconductor layer 2 face each other and are in contact with each other.

In the embodiment, the substrate 6, the oxide buffer layer 5, the alignment layer 4, the surface flatness enhancement layer 3, and the compound semiconductor layer 2 are stacked in this order in the semiconductor stack 1, but a layer formed of another material may be disposed between each layer.

### EXAMPLES

An experiment was conducted to confirm the effects of the semiconductor stack according to the present embodiment. As sample No. 1, a semiconductor stack including a substrate, an oxide buffer layer, an alignment layer, a surface flatness enhancement layer, and a compound semiconductor layer was formed as in the embodiment. As sample No. 2, a semiconductor stack including a substrate, an oxide buffer layer, an alignment layer, and a compound semiconductor layer was formed. As sample No. 3, a semiconductor stack including a substrate, an oxide buffer layer, and a compound semiconductor layer was formed. Sample No. 1 and sample No. 2 are examples. Sample No. 3 is a comparative example.

The orientation and surface flatness were confirmed for each sample. The orientation was evaluated as “A” when the compound semiconductor layer was axially oriented, and as “B” when the compound semiconductor layer was randomly oriented. The “axial orientation” means a state in which the crystal axes can be evaluated as being aligned in the first direction D1. The random orientation means a state other than “axial orientation”. The surface flatness was evaluated as “A” when the ten-point average roughness of the main surface (first main surface) of the compound semiconductor layer is less than 5 nm, and as “B” when it is 5 nm or more.

The results are shown in Table 1.

TABLE 1

| | No. 1 | No. 2 | No. 3 |
|---|---|---|---|
| orientation | A | A | B |
| surface flatness | A | B | B |

As can be seen from Table 1, it was confirmed that the semiconductor stack having the alignment layer was axially oriented and had improved crystallinity as compared with the semiconductor stack having no alignment layer. It was confirmed that the semiconductor stack having the surface flatness enhancement layer had improved surface flatness compared to the semiconductor stack not having the surface flatness enhancement layer.

The embodiment disclosed herein is to be understood as illustrative in every respect and not as restrictive in any way. The scope of the present invention is defined not by the above description but by the scope of the claims, and is intended to include all modifications within the meaning and scope equivalent to the scope of the claims.

What is claimed is:

1. A semiconductor stack comprising:
a substrate formed of silicon;
an oxide buffer layer formed of any of zirconia, hafnia, and a composite oxide of zirconia and hafnia;
an alignment layer formed of gallium arsenide; and
a compound semiconductor layer formed of a III-V compound semiconductor,
wherein the substrate, the oxide buffer layer, the alignment layer, and the compound semiconductor layer are stacked in this order.

2. The semiconductor stack according to claim 1, further comprising:
a surface flatness enhancement layer disposed between the alignment layer and the compound semiconductor layer,
wherein a roughness of a main surface of the surface flatness enhancement layer facing the compound semiconductor layer is smaller than a roughness of a main surface of the alignment layer facing the surface flatness enhancement layer.

3. The semiconductor stack according to claim 1,
wherein a thickness of the alignment layer is smaller than a thickness of the oxide buffer layer.

4. The semiconductor stack according to claim 2,
wherein a thickness of the alignment layer is smaller than a thickness of the oxide buffer layer.

5. The semiconductor stack according to claim 2,
wherein the surface flatness enhancement layer is formed of gallium phosphide or gallium antimonide.
